(19) United States
(12) Patent Application Publication
(10) Pub. No.: US 2006/0191713 A1
(43) Pub. Date: Aug. 31, 2006

(54) Fusible device and method

(76) Inventor: Jeffrey D. Chereson, Erie, PA (US)

Correspondence Address: HODGSON RUSS LLP, ONE M & T PLAZA, SUITE 2000, BUFFALO, NY, 14203-2391, US

(21) Appl. No.: 11/362,675

(22) Filed: Feb. 25, 2006

Related U.S. Application Data
(60) Provisional application No. 60/656,295, filed on Feb. 25, 2005.

(51) Int. Cl. H01H 85/04; H05K 1/11

(52) U.S. Cl. 174/261; 174/250; 337/297

(57) ABSTRACT

Electrically conductive devices and methods of making such devices are disclosed. One such device has a fusible conductor and a substrate. The substrate may support the fusible conductor. The substrate may have an outer perimeter and within the outer perimeter the substrate may have a heat-transfer-resisting material-deficient portion proximate to the fusible conductor.

### CROSS-REFERENCE TO RELATED APPLICATIONS

This application claims the benefit of priority to U.S. provisional patent application Ser. No. 60/656,295, filed on Feb. 25, 2005.

### FIELD OF THE INVENTION

The present invention relates to fusible conductors, such as those used to protect electrical components from high currents.

### BACKGROUND OF THE INVENTION

Fusible conductors have been used on printed circuit boards, as well as other electronic component assemblies, to electrically remove a failed component from a circuit. When a component fails, the current passing to the failed component may increase, and in that situation, the temperature of the conductor delivering that current increases. A portion of the conductor may be made fusible so that when the temperature of the fusible conductor increases, the fusible conductor separates and the conductor no longer carries electricity to the failed component. Separation of the fusible conductor often occurs as a result of the fusible conductor melting or vaporizing as a result of the increased temperature.

By severing the fusible conductor associated with the failed component, the circuit may remain operable and/or other components may be protected from damage. Furthermore, removal of a failed component from an electric circuit may be needed in order to protect personnel from shock and to prevent fire. In order to achieve these desired results, the fusible conductor must electrically sever the conductor soon after the component fails.

When used on circuit boards, fusible conductors will often separate long after the optimum time. Such deviation from the optimum separation time may be due to an inability to control the composition of the material used to make a fusible conductor in a cost effective manner, and/or an inability to control the dimensions of the fusible conductor in a cost effective manner. A new design is needed which minimizes the effects of deviations in material composition and deviations in the dimensions of the fusible conductor.

### SUMMARY OF THE INVENTION

The invention may be embodied as an electrically conductive device having a fusible conductor and a substrate. The substrate may support the fusible conductor. The substrate may have an outer perimeter and within the outer perimeter the substrate may have a heat-transfer-resisting material-deficient portion proximate to the fusible conductor. The term “deficient” is not used herein to indicate a defect, but instead is used to indicate a portion of the substrate where there is less material than in most other portions of the substrate. The substrate may be a circuit board.

The invention may be embodied as a method. In one such method, an electrically conductive device may be created by providing a substrate, placing a fusible conductor on the substrate, and removing material from the substrate proximate to the fusible conductor to provide a heat-transfer-resisting material-deficient portion.

In another method according to the invention, the provided substrate has a heat-transfer-resisting material-deficient portion, and a fusible conductor is placed proximate to the material-deficient portion.

### BRIEF DESCRIPTION OF THE DRAWINGS

For a fuller understanding of the nature and objects of the invention, reference should be made to the accompanying drawings and the subsequent description. Briefly, the drawings are:

FIG. 1, which is a perspective view of a device according to the invention;

FIG. 2A, which is a perspective view of a portion of a device according to the invention;

FIG. 2B, which is a perspective view of the device depicted in FIG. 2A showing a side S2 of the substrate opposite of the side SI depicted in FIG. 2A;

FIG. 3, which is a perspective view of a device according to the invention;

FIG. 4, which depicts a method according to the invention; and

FIG. 5, which depicts a method according to the invention.

### FURTHER DESCRIPTION OF THE INVENTION

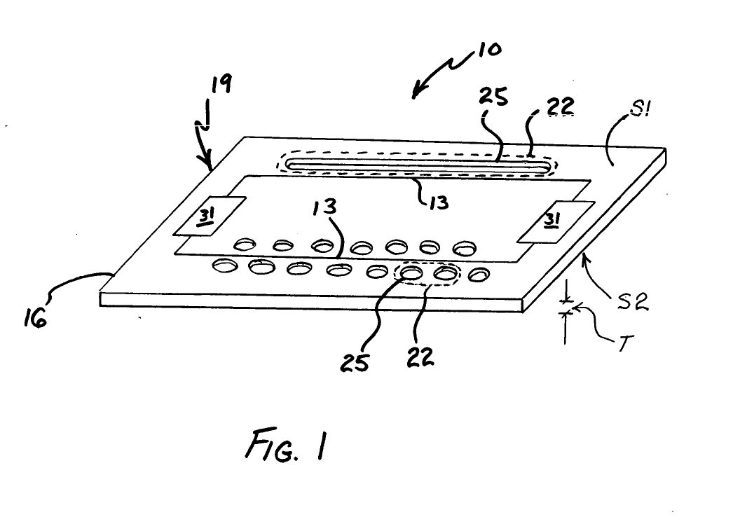

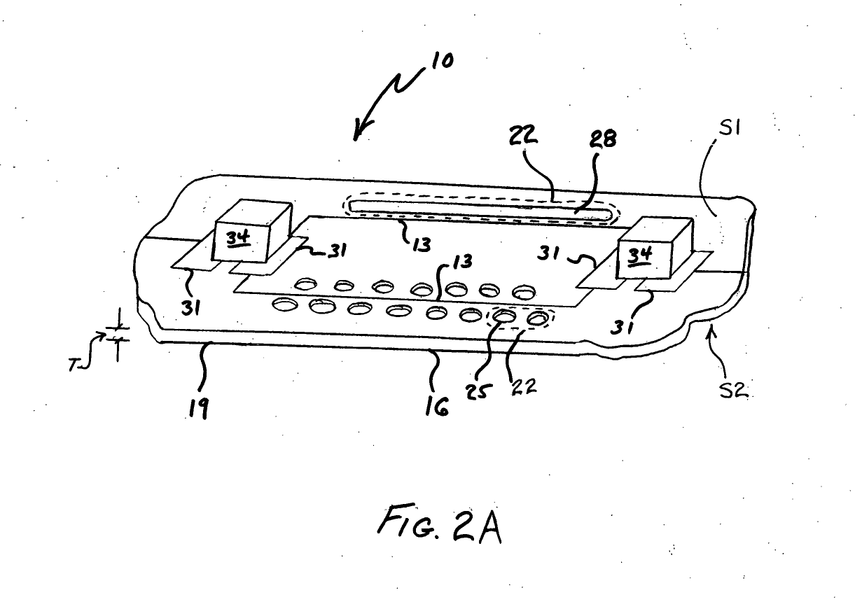

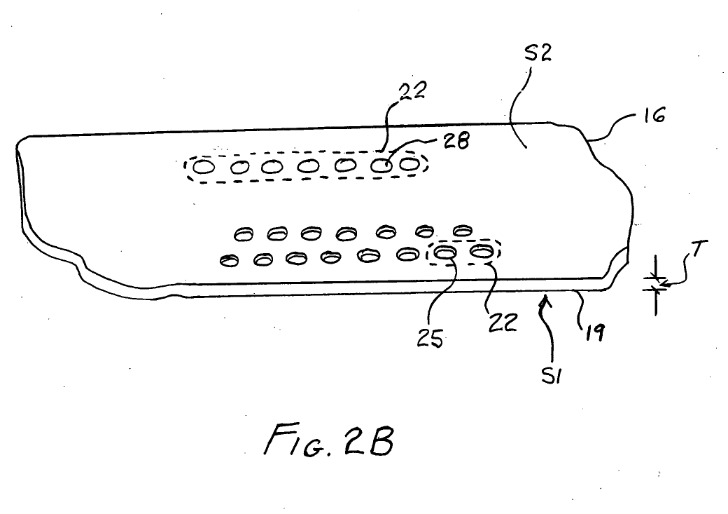

The invention may be embodied as an electrically conductive device 10 having a fusible conductor 13 and a substrate 16. FIG. 1 depicts one such device 10. The fusible conductor 13 may be supported by the substrate 16. The substrate 16 may have an outer perimeter 19, and within that perimeter 19 there may be one or more heat-transfer-resisting material-deficient portions 22 proximate to the fusible conductor 13. For example, the material-deficient portion 22 may have a hole 25 extending through the substrate 16. The hole 25 may take many forms. For example, the hole 25 may be substantially circular, an example of which is shown in FIGS. 1, 2A and 2B. Further, the hole 25 may be a slot, an example of which is shown in FIG. 1.

The heat-transfer-resisting material-deficient portion 22 need not have a hole extending through the substrate 16. For example, the material-deficient-portion 22 may have a reduced thickness area 28 in which the thickness of the substrate 16 is less than the predominant thickness T. FIG. 2A shows an example of such a reduced thickness area 28 that is adjacent to the fusible conductor 13. FIG. 2B shows an example of such a reduced thickness area 28 that is on a side S2 of the substrate 16 that is opposite to the side S1 on which the fusible conductor 13 resides.

It should be noted that the fusible conductor 13 shown in FIG. 2A has been formed on the reduced thickness area 28 shown in FIG. 2B. For purposes, of describing the relative location of the fusible conductor 13 shown in FIG. 2A, if side S1 is placed above side S2, then the fusible conductor 13 will be above the reduced thickness area 28 that is depicted in FIG. 2B (but note FIG. 2A), and there will be another reduced thickness area 28 adjacent to the fusible conductor 13 that is depicted in FIG. 2A (but not FIG. 2B).

The fusible conductor 13 may electrically join two circuit locations 31. Each circuit location 31 may provide conductive material that may be joined to an electrical conditioning component 34. See FIG. 2A. For example, an electrical conditioning component 34 may be a resistor, a capacitor or an inductor.

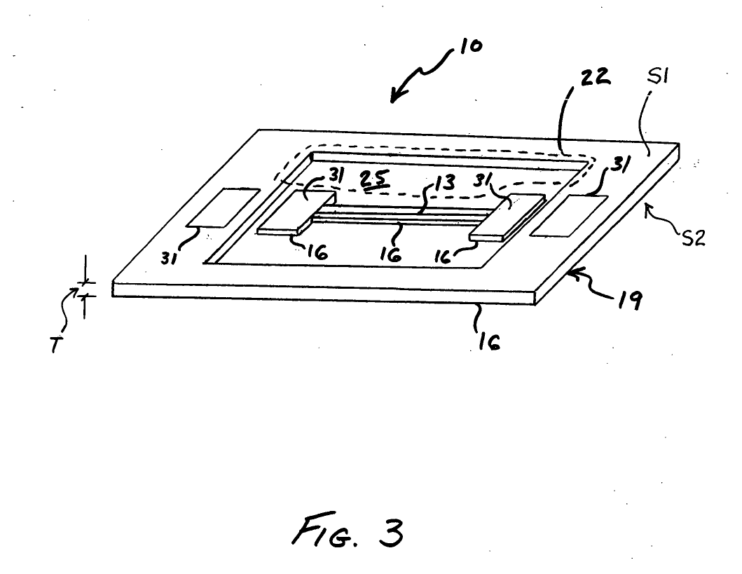

In the embodiments depicted in FIGS. 1 and 2A, the fusible conductor 13 is supported by the substrate 16, and that portion of the substrate 16 that supports the fusible conductor 13 is itself directly supported by other portions of the substrate 16. However, in FIG. 3, the portion of the substrate 16 that supports the fusible conductor 13 is not directly supported by other portions of the substrate 16. Instead, in the embodiment depicted in FIG. 3 the portion of the substrate 16 that supports the fusible conductor 13 is supported via the electrical conditioning component 34. In this manner, the fusible conductor is supported by the conditioning component 34 when installed on the circuit locations 31.

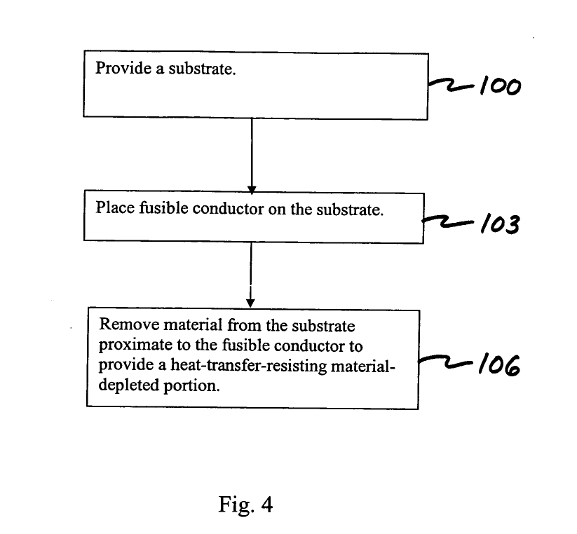

The invention may be embodied as a method. FIG. 4 depicts one such method. In that method, a substrate may be provided 100, and a fusible conductor may be placed 103 on the substrate. Material may be removed 106 from the substrate proximate to the fusible conductor so as to provide a heat-transfer-resisting material-deficient portion. To remove 106 material from the substrate, a drilling, punching or etching operation may be executed. The material-deficient portion may include a hole extending through the substrate, for example a circular hole or slot may be formed. However, the material-deficient portion need not include a hole extending through the substrate. For example, the material-deficient portion may extend only part-way into the substrate.

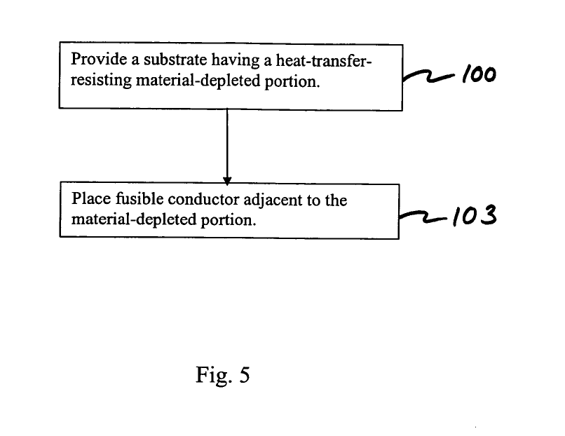

In a variation of the method described above, the material-deficient portion may be formed prior to placing the fusible conductor on the substrate proximate to the material-deficient portion. FIG. 5 describes one such method. For example, the material-deficient portion may be formed when the substrate is formed, and then the fusible conductor may be placed on the substrate proximate to the material-deficient portion. Alternatively, the substrate may be formed, and then material may be removed to provide the material-deficient portion, and then the fusible conductor may be placed on the substrate proximate to the material-deficient portion.

It will now be recognized that the invention may provide a fusible conductor on a substrate near a portion of the substrate where there is less substrate material. By placing the fusible conductor in a region where there is less substrate material, heat transfer from the fusible conductor to the substrate is impeded. By impeding heat transfer from the fusible conductor, an increase in the current carried by the fusible conductor will have a more direct effect on the temperature of the fusible conductor, and therefore, the fusible conductor is more likely to fail at the desired conditions.

U.S. provisional patent application No. 60/656,295 discloses additional details about the invention and additional embodiments of the invention. The disclosure of that patent application is incorporated by this reference.

Although the present invention has been described with respect to one or more particular embodiments, it will be understood that other embodiments of the present invention may be made without departing from the spirit and scope of the present invention. Hence, the present invention is deemed limited only by the appended claims and the reasonable interpretation thereof.

What is claimed is:

1. An electrically conductive device, comprising:
a fusible conductor;
a substrate supporting the fusible conductor, the substrate having an outer perimeter
and within the outer perimeter the substrate has a heat-transfer-resisting material-deficient portion proximate to the fusible conductor.

2. The conductive device of claim 1, wherein the material-deficient portion includes a hole in the substrate.

3. The conductive device of claim 2, wherein the hole is circular.

4. The conductive device of claim 2, wherein the hole is a slot.

5. The conductive device of claim 1, wherein the material-deficient portion includes a reduced thickness area in which a thickness of the substrate in the reduced thickness area is less than a predominant thickness of the substrate.

6. The conductive device of claim 5, wherein the fusible conductor is formed on the reduced thickness area.

7. The conductive device of claim 1, wherein the fusible conductor electrically joins two circuit locations, the circuit locations providing conductive material that may be joined to an electrical conditioning component.

8. The conductive device of claim 7, wherein the fusible conductor is supported by the conditioning component.

9. A method of creating an electrically conductive device, comprising:
providing a substrate;
placing a fusible conductor on the substrate;
removing material from the substrate proximate to the fusible conductor to provide a heat-transfer-resisting material-deficient portion.

10. The method of claim 9, wherein the heat-transfer-resisting material-deficient portion is formed by drilling.

11. The method of claim 9, wherein the heat-transfer-resisting material-deficient portion is formed by punching.

12. The method of claim 9, wherein the heat-transfer-resisting material-deficient portion is formed by etching.

13. The method of claim 9, wherein the heat-transfer-resisting material-deficient portion is a hole.

14. The method of claim 13, wherein the hole is substantially circular.

15. The method of claim 13, wherein the hole is a slot.

16. A method of creating an electrically conductive device, comprising:
providing a substrate having a heat-transfer-resisting material-deficient portion;
placing a fusible conductor proximate to the material-deficient portion.

17. The method of claim 16, wherein providing the substrate is preceded by forming the substrate to have the material-deficient portion.

18. The method of claim 16, wherein providing the substrate is preceded by forming the substrate and then removing material from the substrate to create the material-deficient portion.

19. The method of claim 18, wherein material is removed from the substrate by drilling.

20. The method of claim 18, wherein material is removed from the substrate by punching.

21. The method of claim 18, wherein material is removed from the substrate by etching.

22. The method of claim 16, wherein the heat-transfer-resisting material-deficient portion is a hole.

23. The method of claim 22, wherein the hole is substantially circular.

24. The method of claim 22, wherein the hole is a slot.
